(19) United States
(12) Patent Application Publication
(10) Pub. No.: US 2026/0113880 A1
(43) Pub. Date: Apr. 23, 2026

(54) COOLING DISTRIBUTION UNIT WITH BYPASS LINE

(71) Applicant: LTI Holdings, Inc., Pleasanton, CA (US)

(72) Inventors: Steven J. Medeiros, Loudon, NH (US); Jeffrey A. Henning, Exeter, NH (US)

(21) Appl. No.: 19/359,912

(22) Filed: Oct. 16, 2025

Related U.S. Application Data
(60) Provisional application No. 63/708,564, filed on Oct. 17, 2024.

(51) Int. Cl. H05K 7/20

(52) U.S. Cl. CPC H05K 7/20281; H05K 7/20263; H05K 7/20272

(57) ABSTRACT

A cooling distribution unit includes a portion of a primary closed loop in fluid communication with a cooling structure, a portion of a secondary closed loop in fluid communication with a component to be cooled, a heat exchanger, a bypass line, and a bypass valve. The heat exchanger is in communication with the primary closed loop and the secondary closed loop to transfer heat of the component from the secondary closed loop to the primary closed loop and the cooling structure. The bypass line is capable of fluid communication with the secondary closed loop in parallel with the component, the bypass line having an outlet upstream of the heat exchanger. The bypass valve is in communication with the bypass line and configured to open the bypass line such that the secondary closed loop includes in parallel a component cooling line to gather heat from the component and the bypass line.

### CROSS-REFERENCE TO RELATED APPLICATIONS

This application claims priority to U.S. Provisional Application No. 63/708,564, filed Oct. 17, 2024, the entire contents of which are incorporated herein by reference.

### FIELD

The present disclosure generally relates to cooling distribution units for directing heat away from electrical components.

### BACKGROUND

Cooling distribution units (commonly referred to as CDU's) are often utilized in data centers to remove heat from computer components (e.g., servers and server racks). Cooling distribution units may include, for example, both in-row units and in-rack units. In-row units remove heat from an entire row of server racks or other sets of electrical components, while in-rack units typically remove heat from a single rack or set of electrical components.

### SUMMARY

In accordance with one example, a cooling distribution unit includes a portion of a primary closed loop in fluid communication with a cooling structure; a portion of a secondary closed loop in fluid communication with a component to be cooled; a heat exchanger in communication with the primary closed loop and the secondary closed loop to transfer heat of the component from the secondary closed loop to the primary closed loop and the cooling structure; and a bypass line capable of fluid communication with the secondary closed loop in parallel with the component to be cooled, the bypass line having an outlet upstream of the heat exchanger; and a bypass valve in communication with the bypass line and configured to open the bypass line such that the secondary closed loop includes in parallel a component cooling line to gather heat from the component and the bypass line.

In accordance with another example, a cooling distribution unit includes a portion of a primary closed loop in fluid communication with a cooling structure; a portion of a secondary closed loop in fluid communication with a component to be cooled; a heat exchanger in communication with the primary closed loop and the secondary closed loop to transfer heat of the component from the secondary closed loop to the primary closed loop and the cooling structure; and a bypass line capable of fluid communication with the secondary closed loop in parallel with the component to be cooled, the bypass line having an outlet downstream of the heat exchanger; and a bypass valve in communication with the bypass line and configured to open the bypass line such that the secondary closed loop includes in parallel a component cooling line to gather heat from the component and the bypass line.

In accordance with another example, a cooling distribution unit includes a portion of a primary closed loop in fluid communication with a cooling structure; a portion of a secondary closed loop in fluid communication with a component to be cooled; a heat exchanger in communication with the primary closed loop and the secondary closed loop to transfer heat of the component from the secondary closed loop to the primary closed loop and the cooling structure; and a bypass line capable of fluid communication with the secondary closed loop in parallel with the component to be cooled; a bypass valve in communication with the bypass line and configured to open the bypass line such that the secondary closed loop includes in parallel a component cooling line to gather heat from the component and the bypass line; and a controller in electrical communication with the bypass valve to, the controller capable of automatically actuating the bypass valve.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF THE DRAWINGS

FIG. 1 is a schematic view of a cooling distribution unit in accordance with one example.

FIG. 2 is a perspective view of the cooling distribution unit of FIG. 1.

FIG. 3 is another perspective view of the cooling distribution unit of FIG. 1.

FIG. 4 is another perspective view of the cooling distribution unit of FIG. 1

FIG. 5 is a schematic view of a cooling distribution unit with an electrical component bypass line.

FIG. 6 is a schematic view of a cooling distribution unit with an electrical component and heat exchanger bypass line.

### DETAILED DESCRIPTION

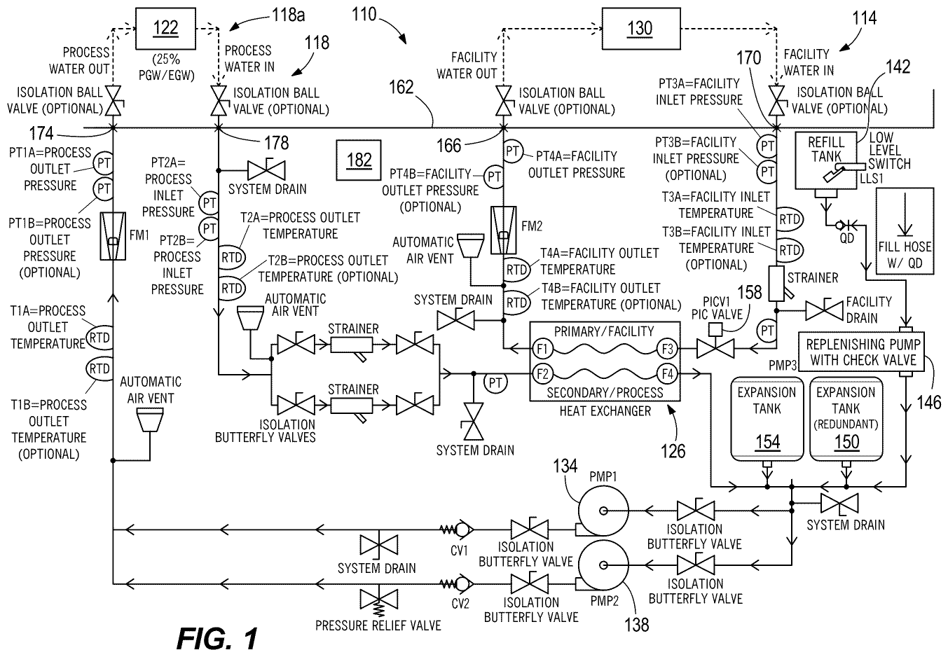

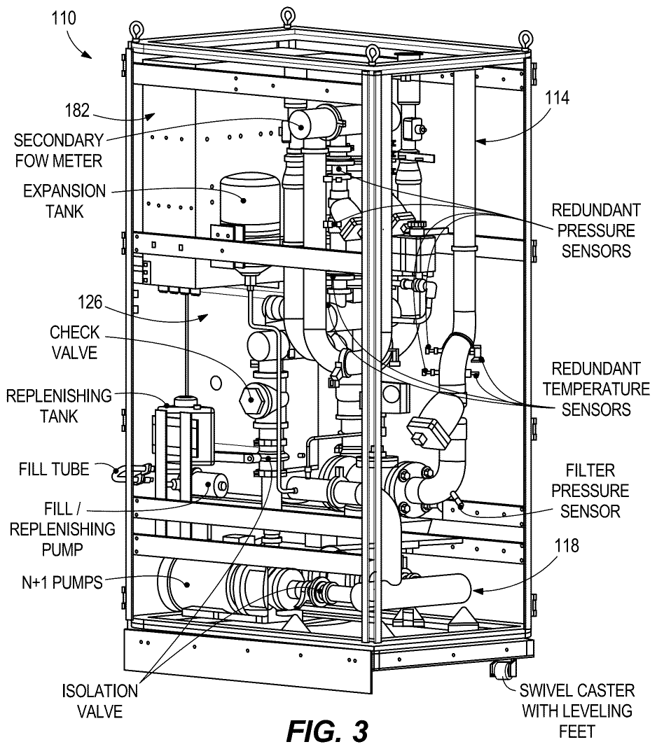

FIGS. 1-4 illustrate an example of a cooling distribution unit 110. The cooling distribution unit 110 may be used in any of a variety of settings, including for example in a server, data center, medical, semiconductor, and/or industrial application. The illustrated cooling distribution unit 110 is an in-row unit, although any of the concepts described herein related to the cooling distribution unit 110 may alternatively be used with an in-rack unit, or with any other type of cooling distribution unit.

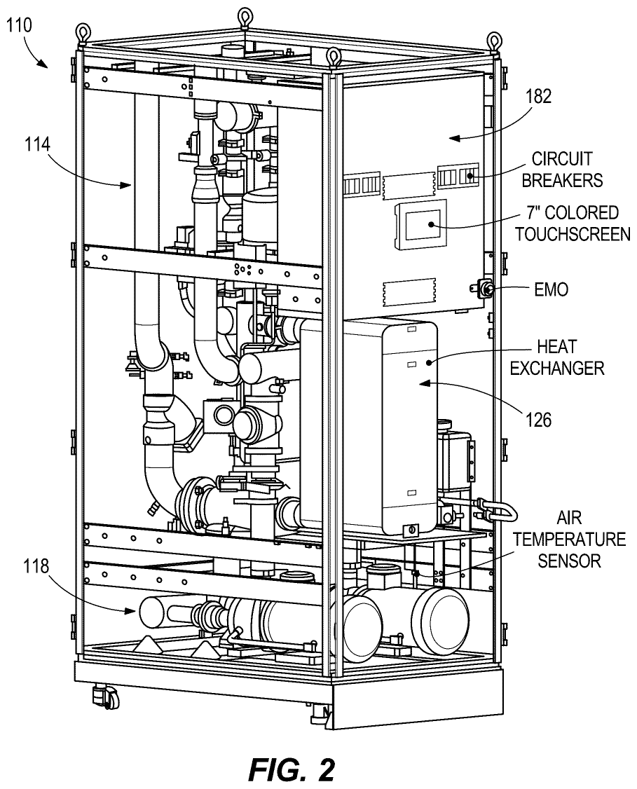

With reference to FIG. 1, the cooling distribution unit 110 generally includes a primary closed loop 114 and a secondary closed loop 118. The primary closed loop 114 circulates a first fluid (e.g., facility water located and/or otherwise supplied at a data server center). The secondary closed loop 118 circulates a second fluid (e.g., a process water solution that includes 25% propylene glycol and 75% water). Other examples include different first and second fluids within either of the primary closed loop 114 or the secondary closed loop 118. As illustrated in FIGS. 2-4, the primary closed loop 114 includes piping (e.g., stainless steel piping) through which the first fluid circulates. The secondary closed loop 118 similarly includes piping (e.g., stainless steel piping) through which the second fluid circulates. Other examples include other types of piping, including piping made of other materials, or having other shapes and configurations than that illustrated.

In some examples, the first fluid may be composed of or include water or propylene glycol-water solutions having a 50% maximum concentration. In other words, the concentration of the glycol-water solution may have a maximum concentration of 10 mg/L. The second fluid may be composed of or include water or a premixed solution of uninhibited ethylene-glycol or propylene-glycol and water. The first fluid and the second fluid may have a largest particle size of less than 200 microns. Other examples may include other materials and/or compositions of materials and/or particle sizes for the first fluid and/or the second fluid.

With continued reference to FIG. 1, the secondary closed loop 118 circulates the second fluid through and/or across one or more electrical components 122, to pick up heat from the electrical components 122. The electrical components 122 may include, for example, computer chips or other heated electrical components in one or more servers or server racks. In some examples, cold plates or other thermal devices may be positioned over the computer chips, and the piping of the secondary closed loop may pass through the cold plates or other thermal devices to pick up the heat from the electrical components 122. Once the second fluid in the secondary closed loop 118 has been heated by the electrical components 122, the heated second fluid is directed to a heat exchanger 126.

With continued reference to FIG. 1, each of the primary closed loop 114 and the secondary closed loop 118 extends through the heat exchanger 126. In the illustrated example, the heat exchanger 126 is a liquid-to-liquid heat exchanger. The primary closed loop 114 directs the first fluid in a first direction (e.g., to the left as viewed in FIG. 1) through the heat exchanger 126, and the secondary closed loop 118 directs the second fluid in a second direction (e.g., to the right as viewed in FIG. 1) through the heat exchanger 126. In the illustrated example, the first direction is parallel to, and opposite, the first direction. In other examples the first fluid and the second fluid may be directed in the same direction, or in a transverse direction, or the first and second fluids may be moved in more than one direction in the heat exchanger 126.

Within the heat exchanger 126, heat is exchanged between the second fluid and the first fluid. Accordingly, at least a portion of the heat picked up (i.e., gathered) from the electrical components 122 is transferred from the second fluid to the first fluid within the heat exchanger 126. In some examples, the piping of the primary closed loop 114 does not contact the piping of the secondary closed loop 118 within the heat exchanger 126, and the heat is exchanged through an intermediary material (e.g., through a thermally conductive material). Other examples may include various other types or number or arrangements of heat exchangers 126 than that illustrated.

With continued reference to FIG. 1, the primary closed loop 114 directs the first fluid (after having been heated in the heat exchanger 126) away from the heat exchanger 126, and to a cooling structure 130. The cooling structure 130 may be located for example within a data server center. The cooling structure 130 may be any of a variety of different structures, including a cooling tower or other thermal device that sheds or otherwise removes heat from the first fluid. In some examples, the cooling structure 130 may include a cold plate, fins, and/or other structures that remove heat, and/or may use a fan or fans to facilitate removal of heat from the first fluid.

As illustrated in FIG. 1, once the heat has been removed from the first fluid at the cooling structure 130, the first fluid is then circulated back toward the heat exchanger 126. Similarly, once the heat has been removed from the second fluid at the heat exchanger 126, the second fluid is circulated back toward the electrical components 122. This circulation through each of the primary closed loop 114 and the secondary closed loop 118 may continue (e.g., for as long as the electrical components 122 are generating heat), such that heat is continuously picked up from the electrical components and delivered to the heat exchanger 126, where the heat is then transferred to the first fluid and the primary closed loop 114, and eventually discarded at the cooling structure 130.

With continued reference to FIG. 1, each of the primary closed loop 114 and the secondary closed loop 118 may include one or more pumps to pump the first fluid and the second fluid through the piping. In the illustrated example, the primary closed loop 114 includes one or more pumps (not illustrated) located within the data server center (e.g., at the location of the cooling structure 130, or elsewhere within the data server center, to pump the first fluid (e.g., facility water) through the primary closed loop 114. The secondary closed loop 118 includes both a first pump 134 and a second pump 138. The first and second pumps 134, 138 are redundant pumps, positioned along parallel lines within the closed loop, such that if one of the pumps fails, the other may continue to operate the overall flow of the second fluid within the secondary closed loop 118. The first pump 134 and the second pump 138 may be any type of pump that is capable of pumping the second fluid. In some examples, the first pump 134 and the second pump 138 are identical pumps, having a same size and/or rating. In some examples, one or more of the first pump 134 or the second pump 138 is a centrifugal pump. Other examples include other types of pumps, and also numbers of pumps. For example, secondary closed loop 118 may in some examples include only a single pump, or may include more than two pumps. Overall, the first pump 134 and/or the second pump 138 may generate a flow rate of for example between 25 gallons per minute (GPM) and 200 GPM (e.g., 25 GPM, 50 GPM, 100 GPM, 125 GPM, 140 GPM, 160 GPM, or other values and ranges of values).

With continued reference to FIG. 1, in some examples the secondary closed loop 118 includes a refill tank 142 and a replenishing pump 146, for adding additional second fluid into the secondary closed loop 118. Additionally, in some examples the secondary closed loop 118 includes at least one expansion tank, for controlling an overall pressure and flow of the second fluid in the secondary closed loop 118. In the illustrated example, the secondary closed loop 118 includes a first expansion tank 150 and a second (e.g., redundant) expansion tank 154. Other examples may include just a single expansion tank, or more than two expansion tanks.

Additionally, both the primary closed loop 114 and the secondary closed loop 118 may include one or more valves (e.g., pressure control valves, check valves, pressure independent control valves, etc.) that operate to control the overall pressure and/or flow of fluid through the cooling distribution unit 110. In the illustrated example, the primary closed loop 114 includes a pressure independent control valve 158.

With continued reference to FIG. 1, in the illustrated example, the cooling distribution unit 110 includes a housing 162 (e.g., an outer housing). The housing 162 may include a steel frame (e.g., with interconnected vertical and/or horizontal frame members), or may be another type of frame, or be formed from different materials. In some examples, the housing 162 includes one or more doors (e.g., pivotally coupled or otherwise coupled to the frame). Other examples may include various other types, sizes, and/or shapes of housing 162 than that illustrated. In the illustrated example, the housing 162 includes a first outlet 166 where the primary closed loop 114 exits, and the first fluid is sent to the cooling structure 130. The housing 162 also includes a first inlet 170, where the primary closed loop 114 enters, and where the first fluid is then directed to the heat exchanger 126 (e.g., located within the housing 162). The housing 162 also includes a second outlet 174, where the secondary closed loop 118 exits and the second fluid is sent to the electrical components 122, and a second inlet 178, where the second fluid enters and is then directed to the heat exchanger 126.

With continued reference to FIG. 1, in some examples, the cooling distribution unit 110 additionally includes one or more sensors that measure pressure, temperature, or other aspects of the system. In the illustrated example, the cooling distribution unit 110 includes a plurality of pressure and temperature sensors (labeled as “PT” and “RTD” in FIG. 1) that are positioned generally at the first outlet 166, the first inlet 170, the second outlet 174, and the second inlet 178. As illustrated in FIG. 1, the cooling distribution unit 110 may include redundant pressure and temperature sensors (e.g., in the event one or more of the sensors fails or provide inaccurate readings).

In some examples, these sensors are coupled (e.g., wired or wirelessly) to a controller 182 (FIGS. 1-4) or other device that receives signals regarding the pressure and temperature of the first fluid and the second fluid. In the illustrated example, the controller 182 is located on and/or within the housing 162, and may include a user interface (e.g., graphical user interface, such as a color touchscreen). In some examples, the controller 182 is located remotely from the housing 162. In some examples, the controller 182 may be used to monitor pressure, monitor temperature, and/or control a flow and pressure differential of the second fluid.

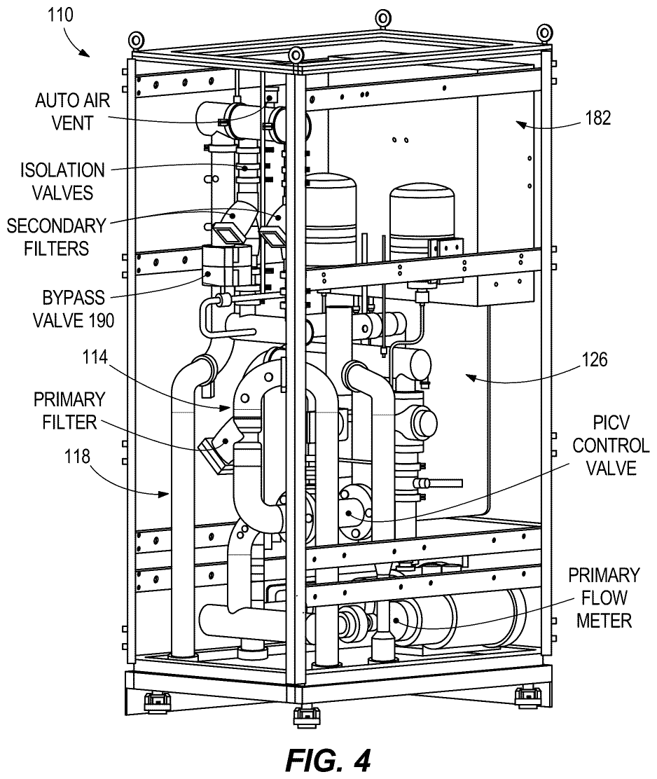

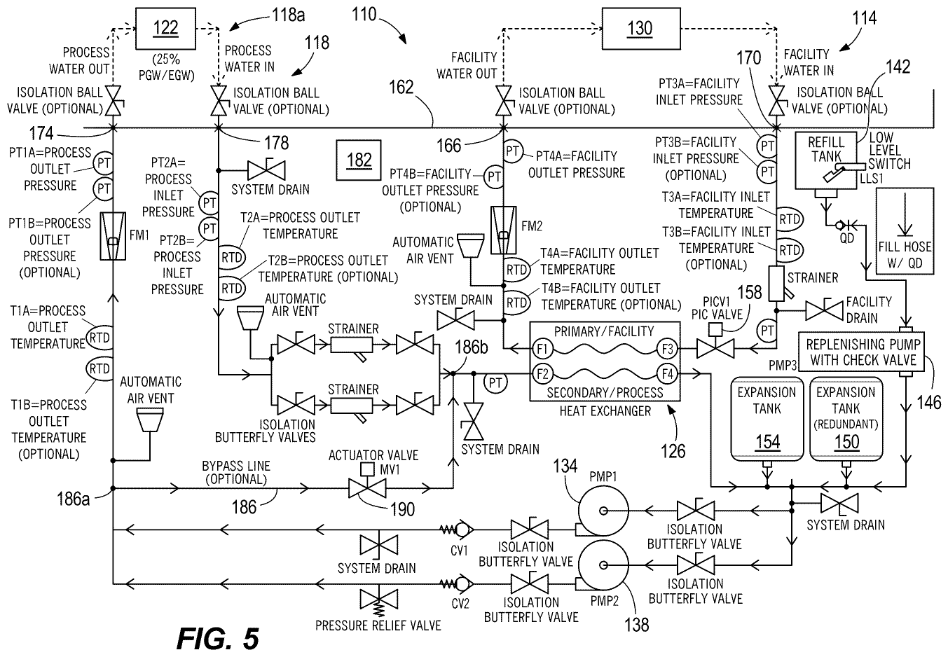

With reference to FIG. 5, the secondary closed loop 118 may optionally include a bypass line 186 (i.e., an electrical component bypass line) and/or a bypass valve 190 (see also FIG. 4). The secondary closed loop 118 includes a component cooling line 118a external to the cooling distribution unit 110. The component cooling line 118a cools the electrical components 122. The bypass line 186 includes an inlet 186a downstream of the pumps 134, 138, and upstream of the second outlet 174 (i.e., upstream of the component cooling line 118a).

In some examples, the bypass line 186 includes an outlet 186b downstream of the second inlet 178 and upstream of the heat exchanger 126 (i.e., downstream of the component cooling line 118a). The bypass line 186 is a portion of the secondary closed loop 118 distinct from the component cooling line 118a. The bypass line 186 allows the second fluid (e.g., the process water solution) to pass through the secondary closed loop 118 bypassing the component cooling line 118a and thus the electrical components 122. In the illustrated example, the bypass line 186 is located entirely within the housing 162. In other examples, at least a portion of the bypass line 186 may be external to the housing 162. Further, in other examples, the first and/or second pumps 134, 138 may be positioned elsewhere in the secondary closed loop 118, for example, upstream of the heat exchanger 126 and/or the outlet 186b of the bypass line 186, so long as motive force for driving the secondary fluid through the secondary closed loop 118 is provided by the first and/or second pumps 134, 138.

The illustrated bypass valve 190 is shiftable between a closed position in which secondary fluid is inhibited from crossing the bypass line 186 and forced through the component cooling line 118a and at least one partially opened position in which secondary fluid is permitted to cross the bypass line 186. With the bypass valve 190 in its closed position, the secondary closed loop 118 is a series loop (e.g., like that illustrated in FIG. 1) defined by a single pathway that forces the secondary fluid through the component cooling line 118a and to be exposed to the electrical components 122. With the bypass valve 190 in an at least partially opened position, the component cooling line 118a and the bypass line 186 form two parallel passageways through the secondary closed loop 118 and through which the secondary fluid passes.

The bypass line 186 and the bypass valve 190 may be designed with appropriate sizes and ratings to transfer secondary fluid therethrough at expected working conditions such as temperature, pressure and volumetric flow rate of the secondary fluid. Further, the material of piping forming the bypass line 186 and the type of bypass valve 190 may be selected to pass the secondary fluid therethrough at the expected working conditions. For example, the bypass valve 190 may be a modulating ball valve of appropriate size and material to allow excess flow not needed for cooling electrical components 122 by the component cooling line 118a.

The bypass valve 190 may be movable (e.g., via the controller 182 or via other components or processes) between its closed position, a plurality of partially opened positions, and to a fully opened position. In some examples, the bypass valve 190 may be movable to a plurality of discrete partially opened positions (e.g., 25% opened, 50% opened, 75% opened, 100% opened, or any other set grouping of partially opened positions). In other examples, the bypass valve 190 may be infinitely adjustable between its closed position and its fully opened position (e.g., any percentage between 0% closed and 100% opened). In some examples, operation of the pump 134 and/or 138 at the operating minimum with the bypass valve 190 closed drives the secondary fluid at a first speed, and operation of the pump 134 and/or 138 at the operating minimum with the bypass valve 190 at least partially opened drives the secondary fluid at a second speed slower than the first speed.

The illustrated bypass valve 190 is positioned between at an intermediate position along the bypass line 186 between the inlet 186a and the outlet 186b. However, in other examples, the bypass valve 190 may be located at either end or any position along the bypass line 186. For example, the bypass valve 190 may be reconfigured as at least one three-way valve positioned at least at the inlet 186a. The outlet 186b may also include a three-way valve.

The bypass valve 190 may be electrically coupled to the controller 182, and the controller 182 can be configured to actuate the bypass valve 190. The controller 182 can be configured to actuate the bypass valve 190 automatically in response to a condition of the cooling distribution unit 110. For example, the controller 182 may actuate the bypass valve 190 based on cooling demand of the electrical components 122. The bypass valve 190 may be electrically coupled to the same controller 182 that operates the first and second pumps 134, 138 and/or a different controller 182. The controller 182 can shift the bypass valve 190 between the fully opened position, the at least one partially opened position, and the closed position. In other examples, the controller 182 can shift the bypass valve 190 simply between its closed position and its fully opened position. The controller 182 may provide one or both of (A) an electrical signal (e.g., a 4-20 mA analog signal) to the bypass valve 190 to initiate an opening or closing sequence of the bypass valve 190 (e.g., to operate a 24DC valve actuator controlled by the 4-20 mA analog signal), and (B) an electrical drive current to the bypass valve 190 to supply an actuator embedded within the bypass valve 190 to open or close the bypass valve 190.

The controller 182 may provide variable frequency drive to the first and/or second pumps 134, 138. Variable frequency drive may facilitate efficient use of input power for driving the pumps 134, 138 (e.g., controlling pump speeds) to meet cooling demand of the electrical components 122. The first and/or second pumps 134, 138 may be supplied high frequency input power upon high demand of cooling the electrical components 122 and low frequency input power upon low demand of cooling the electrical components 122. The variable frequency drive may operate within an operating range including an operating minimum (i.e., operating minimum frequency) and an operating maximum (operating maximum frequency).

When the electrical components 122 generate relatively low amounts of heat (e.g., when a low quantity and/or simple difficulty computations are completed), only a single pump (e.g., the first pump 134) may drive the secondary fluid through the secondary closed loop 118. The first pump 134 may be operated at or near the operating minimum. As a result, the secondary fluid may be driven at a relatively low volumetric flow rate and speed. To further decrease quantity of secondary fluid exposed to the heat of the electrical components 122, the bypass valve 190 can be opened. For example, if the first pump 134 has an operating minimum that corresponds with a volumetric flow rate of 25 gallons per minute (GPM), the bypass valve 190 may be actuated to an at least partially opened position below a threshold volumetric flow rate of, for example, 50 GPM. In other examples, the bypass valve 190 may be actuated at different triggering conditions. Once opened, some of the secondary fluid passes through the bypass line 186 to bypass the electrical components 122. The secondary fluid that passes through the bypass line 186 is not exposed directly to the electrical components 122. At the outlet 186b, the secondary fluid exits the bypass line 186, and may be heated indirectly by the secondary fluid that passed through the component cooling line 118a. Heat may be transferred from the secondary fluid from the component cooling line 118a and to the secondary fluid from the bypass line 186 during mixing and upstream of the heat exchanger 126. The mixed secondary fluid heat is transferred to the primary closed loop 114 via the heat exchanger 126 as described above.

The bypass line 186 and bypass valve 190 provide several advantages. First, the bypass line 186 may provide an expanded lower bound to volumetric flow rate of secondary fluid through the component cooling line 118a below that provided by the series secondary closed loop 118 (e.g., with the bypass valve 190 closed) with the pump 134 at its operating minimum. In some examples, with the bypass valve 190 in a fully opened position and in comparison with the fully closed position, between 10% and 50%, more specifically, between 20% and 40%, or more specifically, approximately 35% less fluid passes through the component cooling line 118a. Fluid crossing the bypass line 186 may also avoid any fluid resistance losses and temperature rise of the component cooling line 118a. As less of the secondary fluid is heated directly by the electrical components 122, and resistance of the component cooling line 118a is avoided, the cooling distribution unit 110 may operate more efficiently. Efficiency improvements may be evident especially in low cooling demand situations where the pump 134 is at its operating minimum. However, even as cooling demand increases, efficiency gains may be realized because the secondary fluid in the bypass line 186 is heated to a lesser extent—with the secondary fluid from the bypass line 186 having not been exposed to the electrical components 122. With the secondary fluid being residually cooler, less input energy (e.g., a lower level of input energy) is required to be applied to the first pump 134 to react to the same cooling demand.

As heat demand increases, the bypass valve 190 may be at least partially closed or entirely closed to increase a proportion of the volumetric flow rate of the secondary closed loop 118 through the component cooling line 118a. The bypass valve 190 may be actuated by the controller 182 to respond proportionally to the heat demand. The controller 182 may operate the first pump 134 or both the first and second pumps 134, 138 above their operating minimum. Thus, more cooling is provided by increasing the volumetric flow rate in the component cooling line 118a and exposed to the electrical components 122.

The controller 182 may be programmed to actuate the bypass valve 190, for example, in accordance with operation of the first and/or second pumps 134, 138. The controller 182 may be capable of responding to low or high cooling demand from the electrical components 122 with appropriate low or high amount of input power operating the first or second pumps 134, 138. The controller 182 may include an onboard memory or be in electrical communication with onboard memory programmed with a control algorithm. The control algorithm may be optimized to limit current of supplied input power to the pump or pumps 134, 138. The control algorithm may additionally or alternatively be optimized to supply minimum amounts of input power to the first and/or second pumps 134, 138. In other words, the first and/or second pumps 134, 138 may be operated as close to their operating minimum (i.e., minimum operating frequency) as possible to meet the cooling demand. Additionally or alternatively, the control algorithm may be optimized to provide target volumetric flow rate in the component cooling line 118a by actuating the bypass valve 190.

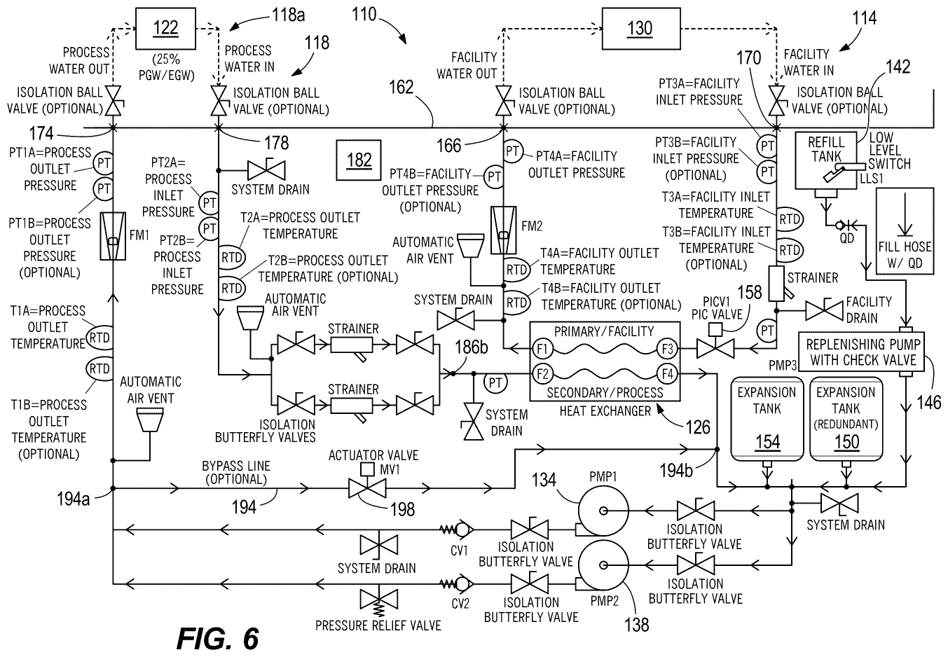

FIG. 6 illustrates another example in which the secondary loop 118 includes including an electrical component and heat exchanger bypass line 194 and an electrical component and heat exchanger bypass valve 198. The heat exchanger bypass line 194 includes an inlet 194a upstream of the second outlet 174 and an outlet 194b downstream of the heat exchanger 126. The electrical component and heat exchanger bypass line 194 and electrical component and heat exchanger bypass valve 198 may function similarly to the bypass line 186 and bypass valve 190 as discussed above. However, the position of the outlet 194b differs from the outlet 186b such that the bypass secondary fluid does not pass through the heat exchanger 126.

When the electrical component and heat exchanger bypass valve 198 is at least partially opened, the secondary closed loop 118 may permit the secondary fluid to flow in parallel through both the heat exchanger 126 and the electrical component and heat exchanger bypass line 194. When the heat exchanger bypass valve 198 is closed, the secondary closed loop 118 may effectively close the electrical component and heat exchanger bypass line 194 and force the secondary fluid to flow through the heat exchanger 126. The electrical component and heat exchanger bypass valve 198 may be electrically coupled to the controller 182, and the controller 182 can be configured to actuate the heat exchanger bypass valve 198. The controller 182 may be configured to adjust the electrical component and heat exchanger bypass valve 198 in a similar manner to the bypass valve 190. For example, the control algorithm of the controller 182 may be optimized to provide target volumetric flow rate of secondary fluid in the secondary closed loop 118 across the heat exchanger 126 and/or to provide target temperature stability of the primary fluid or the secondary fluid.

In some examples, the controller 182 may actuate the electrical component and heat exchanger bypass valve 198 to an at least partially opened position. The electrical component and heat exchanger bypass valve 198 may be opened in situations with low cooling demand due to relatively cool electrical components 122. In such situations, only a portion of the total volumetric flow of secondary fluid in the secondary closed loop 118 passes through the heat exchanger 126, and the remainder of the flow passes through the electrical component and heat exchanger bypass line 194.

The electrical component and heat exchanger bypass valve 198 may movable between its closed position, a plurality of partially opened positions, and a fully opened position. In some embodiments, the electrical component and heat exchanger bypass valve 198 may be movable to a plurality of discrete partially opened positions (e.g., 25% opened, 50% opened, 75% opened, 100% opened, or any other set grouping of partially opened positions). In other embodiments, the bypass valve 190 may be infinitely adjustable between its closed position and its fully opened position (e.g., any percentage between 0% closed and 100% opened).

The electrical component and heat exchanger bypass line 194 and electrical component and heat exchanger bypass valve 198 may enhance the capability of the cooling distribution unit 110 to maintain temperature stability of, for example, the first fluid and/or the second fluid. In certain situations, the pressure independent control valve 158 may be unable to modulate with enough resolution to keep temperature stability of the fluid (e.g., of the first fluid and/or second fluid). For example, the pressure independent control valve 158 may modulate volumetric flow rate of first fluid into the heat exchanger 126. However, the pressure independent control valve 158 may have limits to its modulation (e.g., a lower first fluid flow rate limit). By providing the electrical component and heat exchanger bypass line 194 and electrical component and heat exchanger bypass valve 198, responsibility for resolution required to ensure temperature stability of the fluid (e.g., of the first fluid and/or the second fluid) can effectively be shifted from the pressure independent control valve 158 itself (before inclusion of or opening of the electrical component and heat exchanger bypass valve 198) to both the pressure independent control valve 158 and the electrical component and heat exchanger bypass valve 198.

In the cooling distribution unit 110 of FIG. 6, the pressure independent control valve 158 can control the overall pressure and/or flow of primary fluid through the heat exchanger 126 via the primary closed loop 114, and the electrical component and heat exchanger bypass valve 198 can control the overall pressure and/or flow of secondary fluid through the heat exchanger 126 via the secondary closed loop 118. The controller 182 may actuate both the pressure independent control valve 158 and the electrical component and heat exchanger bypass valve 198 such that desired amounts of fluid pass through each passageway of the heat exchanger 126, and such that temperature stability of the fluid (e.g., first fluid and/or the second fluid) is maintained. In addition to the aforementioned temperature stability benefit, the electrical component and heat exchanger bypass line and valve 194, 198 may avoid fluid resistance losses and temperature rise of the component cooling line 118a as discussed above with regard to the bypass line 186 and bypass valve 190. The electrical component and heat exchanger bypass line 194 and valve 198 may also avoid fluid resistance losses due to the heat exchanger 126 itself. Some heat exchangers 126 include a plurality of turns, which contribute to frictional and fluid resistance losses.

In some examples, the pressure independent control valve 158 is capable of modulating the volumetric flow rate of primary fluid in the primary closed loop 114 through the heat exchanger 126 with a control valve resolution, and the bypass valve 190 is capable of modulating the volumetric flow rate of secondary fluid in the secondary closed loop 118 through the heat exchanger 126 with a bypass valve resolution, and the control valve resolution and the bypass valve resolution each contribute to a system resolution to ensure temperature stability of at least one of the primary fluid and the secondary fluid.

In the illustrated example, the cooling distribution unit 110 has an overall dimension of 31.5″ by 47.4″ by 84.5″, and an overall weight of approximately 1400 pounds. Other examples may include various different sizes and weights, including sizes smaller and larger than that illustrated, and weights smaller or greater than that illustrated. Additionally, in the illustrated example, the cooling distribution unit 110 may provide a cooling capacity of 550 KW (at 4° C. approach temperature difference) and 1100 KW (at 8° C. approach temperature difference). Other examples may include other values and ranges of values of cooling capacity, including a cooling capacity smaller or greater than that illustrated.

Although various aspects and examples have been described in detail with reference to certain examples illustrated in the drawings, variations and modifications exist within the scope and spirit of one or more independent aspects described and illustrated.

What is claimed is:

1. A cooling distribution unit comprising:
a portion of a primary closed loop in fluid communication with a cooling structure;
a portion of a secondary closed loop in fluid communication with a component to be cooled;
a heat exchanger in communication with the primary closed loop and the secondary closed loop to transfer heat of the component from the secondary closed loop to the primary closed loop and the cooling structure;
a bypass line capable of fluid communication with the secondary closed loop in parallel with the component to be cooled, the bypass line having an outlet upstream of the heat exchanger; and
a bypass valve in communication with the bypass line and configured to open the bypass line such that the secondary closed loop includes in parallel a component cooling line to gather heat from the component and the bypass line.

2. The cooling distribution unit of claim 1, wherein the bypass valve is shiftable to a closed position to force a fluid of the secondary closed loop through the component cooling line.

3. The cooling distribution unit of claim 2, further comprising a controller electrically coupled to the bypass valve and configured to shift the bypass valve between an at least partially opened position and the closed position.

4. The cooling distribution unit of claim 2, further comprising a controller electrically coupled to a pump that provides motive force to secondary fluid in the secondary closed loop, the controller providing a variable frequency drive with an operating range including an operating minimum.

5. The cooling distribution unit of claim 4,
wherein operation of the pump at the operating minimum with the bypass valve closed drives the secondary fluid at a first speed, and
wherein operation of the pump at the operating minimum with the bypass valve at least partially opened drives the secondary fluid at a second speed slower than the first speed.

6. The cooling distribution unit of claim 4,
wherein operation of the pump at the operating minimum with the bypass valve closed requires a first level of input energy to the pump, and
wherein operation of the pump at the operating minimum with the bypass valve opened requires a second level of input energy to the pump, the second level of input energy being lesser than the first level of input energy.

7. The cooling distribution unit of claim 1, wherein the bypass valve is adjustable between a plurality of at least partially opened positions and to a fully opened position.

8. The cooling distribution unit of claim 1, further comprising a housing within which the portion of the primary closed loop, the portion of the secondary closed loop, the heat exchanger, the bypass line, and the bypass valve are positioned.

9. A cooling distribution unit comprising:
a portion of a primary closed loop in fluid communication with a cooling structure;
a portion of a secondary closed loop in fluid communication with a component to be cooled;
a heat exchanger in communication with the primary closed loop and the secondary closed loop to transfer heat of the component from the secondary closed loop to the primary closed loop and the cooling structure;
a bypass line capable of fluid communication with the secondary closed loop in parallel with the component to be cooled, the bypass line having an outlet downstream of the heat exchanger; and
a bypass valve in communication with the bypass line and configured to open the bypass line such that the secondary closed loop includes in parallel a component cooling line to gather heat from the component and the bypass line.

10. The cooling distribution unit of claim 9, wherein the bypass valve is shiftable to a closed position in which fluid of the secondary closed loop flows through the heat exchanger and not the bypass line.

11. The cooling distribution unit of claim 10, further comprising a controller electrically coupled to the bypass valve and configured to shift the bypass valve between the closed position and an at least partially opened position.

12. The cooling distribution unit of claim 11, wherein the controller is programmed with a control algorithm to optimize volumetric flow rate of secondary fluid through the heat exchanger by actuating the bypass valve.

13. The cooling distribution unit of claim 9, further comprising a control valve in communication with the portion of the primary closed loop, the control valve capable of being opened to modulate a volumetric flow rate of primary fluid in the primary closed loop through the heat exchanger.

14. The cooling distribution unit of claim 13, wherein the control valve is capable of modulating the volumetric flow rate of primary fluid in the primary closed loop through the heat exchanger with a control valve resolution, and wherein the bypass valve is capable of modulating the volumetric flow rate of secondary fluid in the secondary closed loop through the heat exchanger with a bypass valve resolution, where the control valve resolution and the bypass valve resolution each contribute to a system resolution to ensure temperature stability of at least one of the primary fluid and the secondary fluid.

15. A cooling distribution unit comprising:
a portion of a primary closed loop in fluid communication with a cooling structure;
a portion of a secondary closed loop in fluid communication with a component to be cooled;
a heat exchanger in communication with the primary closed loop and the secondary closed loop to transfer heat of the component from the secondary closed loop to the primary closed loop and the cooling structure;
a bypass line capable of fluid communication with the secondary closed loop in parallel with the component to be cooled;
a bypass valve in communication with the bypass line and configured to open the bypass line such that the secondary closed loop includes in parallel a component cooling line to gather heat from the component and the bypass line; and
a controller in electrical communication with the bypass valve to, the controller configured to automatically actuate the bypass valve.

16. The cooling distribution unit of claim 15, further comprising a pump electrically coupled to the controller, the pump configured to drive secondary fluid of the secondary closed loop,
wherein the controller is configured to supply input power to the pump and to operate the pump at a pump speed based on a cooling demand of the component to be cooled.

17. The cooling distribution unit of claim 16, wherein the controller is programmed with a control algorithm to optimize a quantity of supplied input power to the pump based on the cooling demand.

18. The cooling distribution unit of claim 17, wherein the control algorithm is optimized to target a desired volumetric flow rate to be exposed to the component cooling line by actuating the bypass valve.

19. The cooling distribution unit of claim 17, wherein the control algorithm is optimized to limit a current of the supplied input power to the pump by actuating the bypass valve.

20. The cooling distribution unit of claim 15, wherein the bypass line has an outlet upstream of the heat exchanger.
